(19) United States
(12) Patent Application Publication
(10) Pub. No.: US 2008/0273165 A1
(43) Pub. Date: Nov. 6, 2008

(54) METHOD AND APPARATUS FOR REDUCING EXPOSURE TO RF ENERGY PRODUCED BY PORTABLE TRANSMITTERS

(76) Inventors: Roy J. Mankovitz, Montecito, CA (US); Lawrence Karr, Santa Monica, CA (US); Paula Mayerson, Santa Monica, CA (US)

Correspondence Address: GIFFORD, KRASS, SPRINKLE,ANDERSON & CITKOWSKI, P.C, PO BOX 7021, TROY, MI, 48007-7021, US

(21) Appl. No.: 11/743,395

(22) Filed: May 2, 2007

(51) Int. Cl. G02C 11/00; G01R 23/02

(52) U.S. Cl. 351/158; 250/250

(57) ABSTRACT

Apparatus and methods for reducing the exposure of a human eye to external radio frequency (RF) radiation comprises eyeglass frames and/or a lens, positioned in front of the eye, and a material, intentionally added on or in the frames or lens, which is operative to shield, attenuate, or reflect high-frequency RF energy. The invention is also applicable to contact lenses without frames. The invention is also effective in shielding the human brain and other tissues. In the preferred embodiments, the material is operative to shield, attenuate, or reflect energy in the range of 100 MHz to 30 GHz and/or provide an RF power reduction of at least 25 percent. The material may include ferrite beads. Embedded components may include an RF detector and circuitry to actively attenuate the level of RF energy received in response to the detected level, or an RF detector and circuitry to alert a user as to the level of RF energy received in response to the detected level. The alert may be visual or audible.

### FIELD OF THE INVENTION

This invention relates generally to radio-frequency and microwave radiation and, in particular, to an apparatus and methods for protecting the human eye, brain and other tissue from exposure to such radiation.

### BACKGROUND OF THE INVENTION

The effects of exposure to electromagnetic radiation have long been a subject of debate among scientists. The technological developments of the last twenty years such as cell and cordless phones, wireless communications, monitors and even high-voltage lines have all been studied as potential risk factors for cancer and other diseases. Less known to the public, but still a matter of some extensive research, is the study of the effect of microwave radiation on the visual system and especially on the lens of the eye. The basic motivation for this research came from the observation that World War II radio operators appeared to suffer an increased incidence of later developing cataracts, a condition characterized by clouding within the natural lens of the eye. Although these early studies were inconclusive, the safety concerns they raised led to the establishment of the first guidelines for human exposure to electromagnetic radiation. The eye is our natural radiation detector and is therefore an optimal local for the investigation of the effect of electromagnetic radiation upon the human body.

In a recent scientific study conducted by a team of researchers from the Technion Israel Institute of Technology, a possible link was found between microwave radiation, similar to the type generated by cellular phone transmitters, and different kinds of damage to the visual system. At least one type of damage to the human lens appears to accumulate over time without healing, thus challenging the common view that the duration of exposure is less important than the intensity of the irradiation. Technion researchers came to the conclusion that existing exposure guidelines for microwave radiation needed to be reevaluated.

Recent animal studies revealing microwave radiation as a risk factor for cataracts, have led to a revision, in 1998, of safety guidelines recommended by the International Commission on Non-Ionizing Radiation Protection (ICNIRP) in 1998. A common measure for microwave radiation is the Specific Absorption Rate (SAR), defined as the average power density absorbed in a given volume per average weight density (Watt/Kg). This standard is used by cell phone companies to measure radiation levels. When microwave energy impinges upon body tissue, ionic conduction results in some of the energy being converted into heat, which causes elevated temperatures within the exposed tissue.

Animal studies have demonstrated that a temperature increase as small as three degree Celsius, which occurs adjacent to the lens, can increase the risk of cataract formation. Keeping the SAR low could protect lens tissue from overheating. A less common type of measurement is called Specific Energy Absorption (SA), defined as the energy density absorbed in the tissue divided by its weight density. While SAR measures the rate that microwave radiation is absorbed by a tissue, SA measures the total energy absorbed. This difference was the focus of a recent study on the effects of microwave radiation on cataract development.

Researchers at the Rappaport Faculty of Medicine at Technion Institute have recently published a study, in the journal Bioelectromagnetics, showing a link between microwave radiation and cataract development. Bovine lenses from one-year-old male calves were obtained in pairs from a slaughterhouse. One lens from each calf was exposed to microwave radiation while the other lens was left untreated for the experimental control. Each exposure session lasted about two weeks. Each pair of lenses, both exposed and control, were kept in an incubator at constant temperature. Lenses were treated with 2 mW of continuous 1.1 GHz radiation for each exposure period. Each treatment session included a 50 minute exposure followed by a 10 minute break. Once every 24 hours, every lens was optically tested and compared to its control lens from the same calf. During the short (5 minute duration) optical test, the lens was not exposed to radiation. The average temperature of the lens was maintained at constant level by irradiating the tissue while inside an incubator

The Rappaport study yielded a number of interesting results. First, it was found that exposing the lens for a prolonged time to microwave radiation caused macroscopic damage which decreased the optical quality of the treated lens. This damage increased as the experiment and irradiation continued, reaching a maximum level after several days. When the exposure stopped the optical damage began to heal gradually. Interestingly enough, a similar maximum level was observed when irradiation intensity was reduced by one-half and exposure time was doubled.

A second finding of this study was that a different kind of damage occurred at the microscopic level. Tiny “bubbles” were created on the surface of the lens. This study ruled out thermal effects of radiation as the cause of damage to the lens. Thus microwave radiation itself, hot heating of the lens, were responsible for the creation of the bubbles. The researchers speculated that the mechanism responsible is the microscopic friction between particular cells exposed to electromagnetic radiation. Contrary to the macroscopic damage, the microscopic damage did not show any signs of healing and continued to accumulate throughout the course of the experiment.

While the researchers were cautious in interpreting their results and its possible implications to public health, it seems that prolonged exposure to microwave radiation similar to that used by cellular phones can lead to both macroscopic and microscopic damage to the lens, and that at least part of this damage seems to accumulate over time and appears not to heal. Professor Levi Schachter, one of the researchers in this study, suggested that attention be paid not only to the Specific Absorption Rate (SAR) but also to the total energy absorbed by the tissue (SA), which is not currently under supervision by the appropriate regulative authorities.

The tests done at the Technion apparently used a parallel plate transmission line system, where the electric field strength could be computed as the voltage on the transmission line divided by the conductor spacing. The absorption is dependent on the loss properties of the test specimens. If a cell phone has a maximum radiated power approaching a watt, then the theoretical isotropic radiator calculations yield a power density which is power/(4*pi*r*r) and results in milliwatts per square centimeter. It is difficult to know what the real absorbed power densities are, since tissue has very high radio frequency loss, increasing as a function of frequency. The field strength at the cornea is probably quite high, since it is exposed, but the microwave properties of the aqueous humor between the cornea and the lens, which is presumably a saline solution, are not well defined. Despite all of these caveats, it still seems far more likely that eye damage might occur in addition to brain tumors resulting from exposure to cell-phone radiation.

### SUMMARY OF THE INVENTION

This invention broadly resides in apparatus and methods for reducing exposure to external radio frequency (RF) radiation of the type experienced when a person uses a cell phone or other device having an RF transmitter One embodiment comprises a lens, positioned in front of the eye, and a material, intentionally added on or in the lens, which is operative to shield, attenuate, or reflect high-frequency RF energy. The lens may be an eyeglass lens or a contact lens. In the preferred embodiments, the material is operative to shield, attenuate, or reflect energy in the range of 100 MHz to 30 GHz and/or provide an RF power reduction of at least 25 percent. The material may be embedded in, or applied to, the lens, while being sufficiently optically transparent that it does not adversely impair the vision of a user.

A different embodiment comprises a set of eyeglass frames, and a material or components, intentionally added on or in the frames, operative to shield, attenuate, or reflect high-frequency RF energy, or alert the user that they may be exposed to an undesirable level of high-frequency RF energy. Since the frames may not be transparent or translucent, the material may include ferrite beads. Again, however, the material is preferably operative to shield, attenuate, or reflect energy in the range of 100 MHz to 30 GHz, and/or provide an RF power reduction of at least 25 percent. The components may include an RF detector and circuitry to actively attenuate the level of RF energy received in response to the detected level, or an RF detector and circuitry to alert a user as to the level of RF energy received in response to the detected level. The alert may be visual or audible.

### BRIEF DESCRIPTION OF THE DRAWINGS

FIG. 1 is a drawing of eyeglass frames with a cut-away portion showing the use of RF energy absorptive or reflective material;

FIG. 2 is a drawing that shows the use of an attachable drape or shield;

FIG. 3 is a drawing that shows the beneficial use of a wrap-around lens design;

FIG. 4 is a drawing that shows an RF detector and circuitry to alert a user as to the level of RF energy received in response to the detected level;

FIG. 5 is a drawing that shows an RF detector and circuitry to actively attenuate the level of RF energy received in response to the detected level;

FIG. 6 is a drawing that illustrates application of the invention to a contact lens;

FIGS. 7A-C show different configurations providing improved shielding for reducing brain exposure; and

FIGS. 8A-C show different configurations providing improved shielding for reducing brain exposure along with a sound-permeable mesh or other type of membrane.

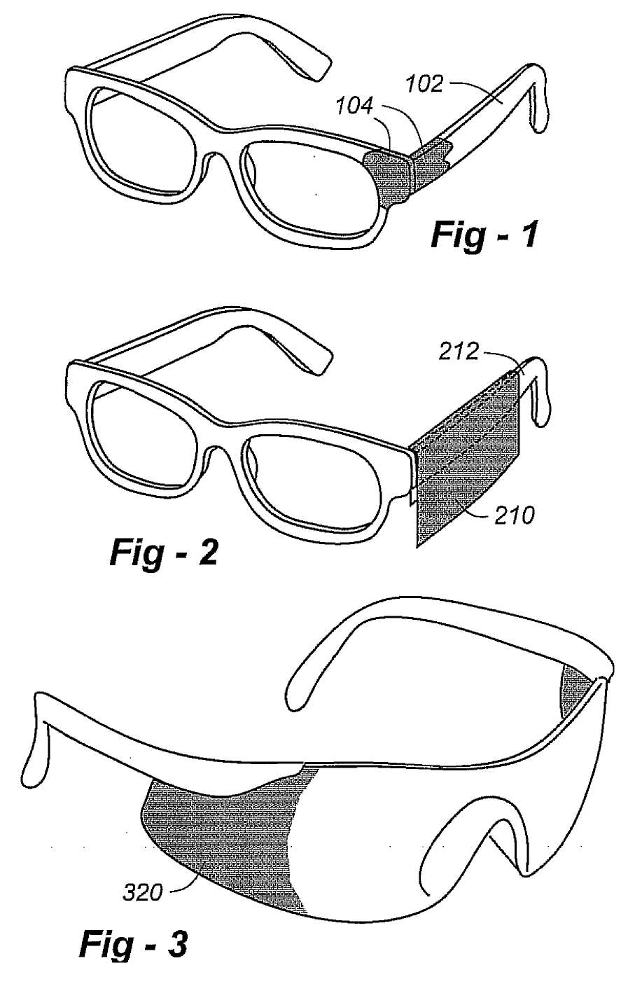

### DETAILED DESCRIPTION OF THE INVENTION

One objective of this invention is to build into eyeglass frames, eyeglass lenses and contact lenses, suitable radio frequency (RF) absorption, reflection, shielding, or other effects, so as to reduce the radio frequency field strength at the human brain and/or eye, particularly the cornea, lens and retina.

In the preferred embodiments, RF attenuation is provided for part or all of the RF spectrum extending from 100 MHz to 30 GHz. The RF spectrum of major interest is that currently used for cell-phone transmissions, in the range of 800 MHz to 2 GHz. This frequency range is alternately referred to as a UHF frequency range or an L or S band microwave frequency range. In the case of a cell phone, the RF emitter is so close to the relevant eye structures and other vulnerable tissues in the near field of the emitter. For 35 cm waves, a typical distance of 8 or 9 cm would be within a quarter wavelength.

It is also intended that the invention provide RF power attenuation of 25 percent (−1 dB) or more of the power level without the implementation of the invention. In particular, the goal is to provide RF power attenuation at the brain, eye or other exposed tissues to a level which is 50 percent (−3 dB) or more. Another objective is to provide an eyeglass frame which includes a visual indicator to alert the user when cell-phone RF power exceeds a predetermined level.

Yet another objective is to provide an eyeglass frame which includes adaptive filter circuitry to sense and automatically adjust RF filter parameters to minimize the amount of RF energy.

### Eyeglass Frame Embodiments

### Metal Frames

According to this invention, eyeglass frames 102 constructed of metal contain a plurality of small ferrite beads 104. Alternatively a ferrite sleeve 210 is clamped over the ear pieces 212 of the frame, spaced apart along the length from the ear to the front of the frame. It is well known that ferrite can act as an attenuator of electromagnetic energy, and can reduce the amount of such energy transmitted along the metal frame from the ear of a user holding a cell phone thereto, to the vicinity of the eye. The sleeve 210 is also configured to reduce brain exposure.

As shown in FIG. 3, the eyeglasses may incorporate “wrap around” pieces 320 at the outer edges of the lenses, which pieces serve to attenuate the aforementioned field strength. These pieces would incorporate thin, partially transparent conductive films or embedded particles of metal or other conductive or reactive substances to reduce field strength.

### Plastic Frames

In eyeglass frames constructed of plastic, microwave energy absorptive materials such as carbon are embedded or molded into the plastic along the entire length of the frame during its manufacture. The object would be to construct a frame which would absorb substantial amounts of microwave energy in the relevant spectrum, reducing the amount that might impinge upon the wearer from external sources such as cell phones. Side pieces may also be used as discussed in conjunction with metal frame embodiments.

Frames with Visual RF Power Indicators

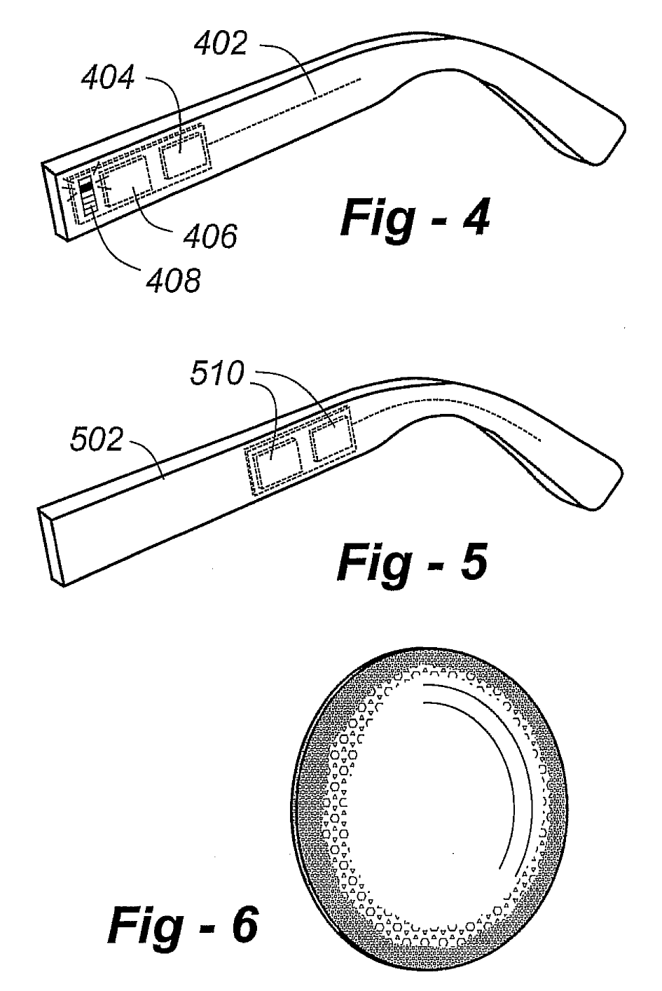

In this embodiment of the invention, shown in FIG. 4, an antenna 402, tuned circuitry 404, and an RF driven power supply 406 would be embedded into the frame ear pieces adjacent one or both ears. The power supply is connected to a visual indicator 408 such as an LED, the light of which can be dispersed throughout the length of the frame using suitably embedded optical fibers in a manner that the LED illumination can be seen by the user of the eyeglasses while they are being worn. An audible alert may also be used.

The RF driven power supply would be constructed in a manner similar to that used in RFID chips, where the incoming RF energy is used to power the device, in this case an LED. Threshold circuitry may be built into the device so that the LED emits light only when the RF energy emitted from a cell phone held near the ear exceeds a predetermined level that is deemed to be of danger to the user. Alternatively, the LED could be flashed at a rate indicative of the RF power level, or a bar-graph display may be used. Because cell phone circuitry uses adaptive transmitter power control, this embodiment can be useful in alerting the user when it might be prudent to terminate a call or increase the distance between the cell phone and the user.

Frames with Adaptive Filter Circuitry

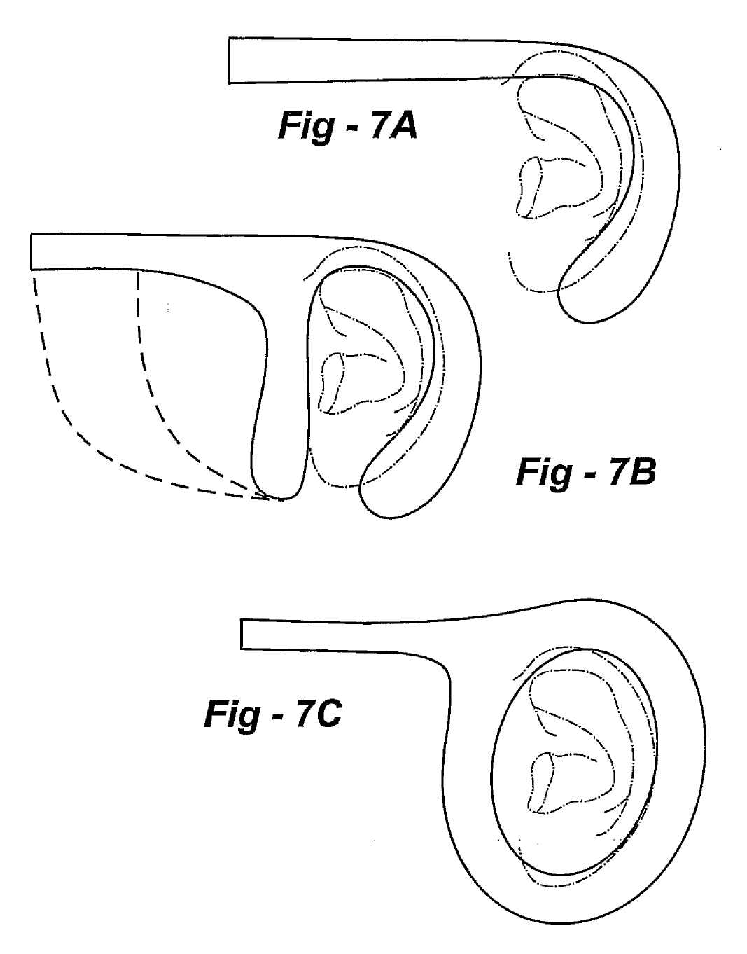

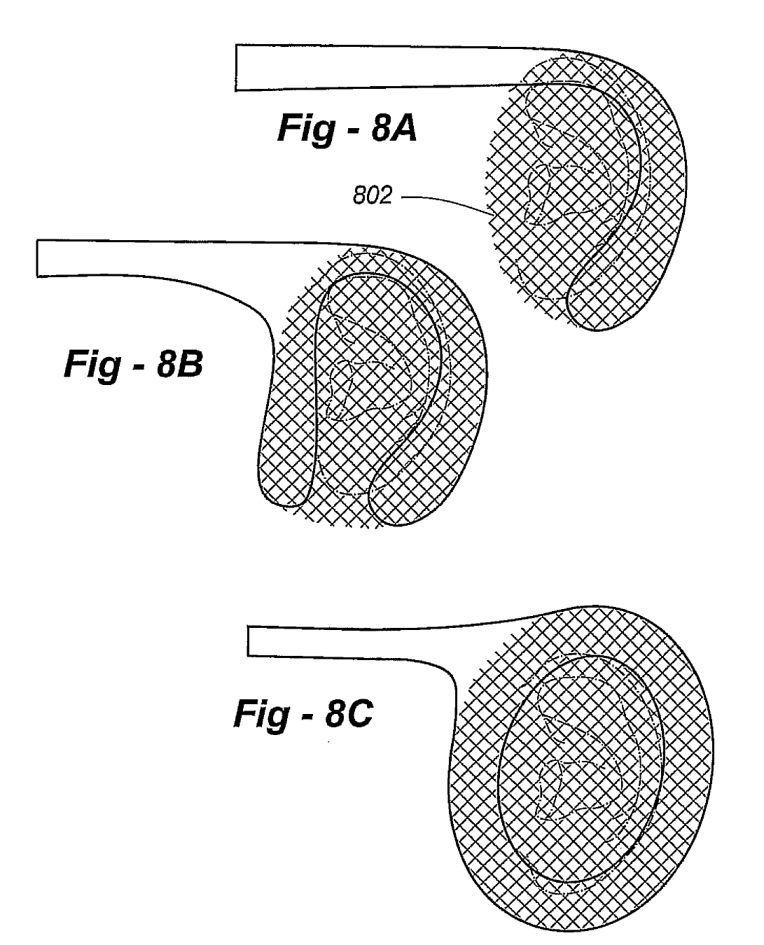

In this embodiment, shown in FIG. 5, the frame 502 includes RF powered circuitry 510 that would measure the RF field intensity from the cell phone and adaptively adjust filter conductance and/or capacitance values to minimize that field, using local currents or the like to minimize or nullify the eye exposure to RF. It will be appreciated that the electronic-circuit based implementations discussed with respect to FIGS. 4 and 5 are applicable to all of the embodiments disclosed herein, including the embodiments of FIGS. 7A-8C which help to protect the brain and other tissues.

### Eyeglass Lens and Contact Lens Implementations

In these embodiments the objective is to coat and/or imbed into the lens materials which have substantial absorptive properties in the relevant microwave band. Examples would include the embedding of metal and/or carbon filaments and/or carbon particles in a manner that does not affect the transmission of visible light through the lens, and hence is not observable by the wearer. As shown in FIG. 6, the concentration of the absorptive materials may be maximized around the periphery of the lens, leaving the central, pupil-covering region more visually transparent. The coating may be applied to these lenses, perhaps using nanoparticle technology, to provide microwave absorption without disturbing the optical properties. This embodiment is not limited to contact lenses, in that it may be applied to lenses in eyeglass frames as well. It should be noted here that the metallic coatings applied to office building windows and to heated automobile windshields very considerably attenuate microwave or radio frequency radiation.

### Embodiments Protecting the Brain and Other Tissues

FIGS. 7A-C show different configurations providing improved shielding for reducing exposure to the brain and other soft tissues. In FIG. 7A, the back of the ear piece extends lower than typical, and may include any of the apparatus and methods disclosed herein for enhancing radio frequency (RF) absorption, reflection, or shielding. In FIG. 7B, an addition component forward of the ear is provided, with the broken lines indicating other side shield configurations. In FIG. 7B the barrier extends all the way around the wearer's ear. FIGS. 8A-C show different configurations providing improved shielding for reducing brain and tissue exposure along with a sound-permeable mesh or other type of membrane 802.

We claim:

1. Apparatus for reducing the exposure of human body parts to external radio frequency (RF) radiation, comprising:
a lens, positioned in front of the eye; and
a material, intentionally added on or in the lens, which is operative to shield, attenuate, or reflect high-frequency RF energy.

2. The apparatus of claim 1, wherein the lens is an eyeglass lens.

3. The apparatus of claim 1, wherein the lens is a contact lens.

4. The apparatus of claim 1, wherein the material is operative to shield, attenuate, or reflect energy in the range of 100 MHz to 30 GHz.

5. The apparatus of claim 1, wherein the material provides an RF power reduction of at least 25 percent.

6. The apparatus of claim 1, wherein the material is embedded in the lens and is sufficiently optically transparent that it does not adversely impair the vision of a user.

7. The apparatus of claim 1, wherein the material is a coating on the lens and is sufficiently optically transparent that it does not adversely impair the vision of the user.

8. The apparatus of claim 1, wherein:
the lens is an eyeglass lens supported in eyeglass frames; and
at least a portion of the eyeglass frames includes a material which is operative to shield, attenuate, or reflect high-frequency RF energy.

9. The apparatus of claim 8, wherein the material in the eyeglass frames includes ferrite beads.

10. Apparatus for reducing the exposure of human body parts to external radio frequency (RF) radiation, comprising:
eyeglass frames; and
a material or components, intentionally added on or in the frames, operative to shield, attenuate, or reflect high-frequency RF energy, or alert the user that they may be exposed to an undesirable level of high-frequency RF energy.

11. The apparatus of claim 10, wherein the material includes ferrite beads.

12. The apparatus of claim 10, wherein the material is operative to shield, attenuate, or reflect energy in the range of 100 MHz to 30 GHz.

13. The apparatus of claim 10, wherein the material provides an RF power reduction of at least 25 percent.

14. The apparatus of claim 10, wherein the material includes ferrite beads.

15. The apparatus of claim 10, wherein the components include:
an RF detector; and
circuitry to actively attenuate the level of RF energy received in response to the detected level.

16. The apparatus of claim 10, wherein the components include:
an RF detector; and
circuitry to alert a user as to the level of RF energy received in response to the detected level.

17. The apparatus of claim 16, wherein the alert is a visual alert.

18. The apparatus of claim 16, wherein the alert is an audible alert.
